(19) United States
(12) Patent Application Publication
(10) Pub. No.: US 2011/0037976 A1
(43) Pub. Date: Feb. 17, 2011

(54) FLEXIBLE SURFACE ENHANCED RAMAN SPECTROSCOPY (SERS) SUBSTRATES, METHODS OF MAKING, AND METHODS OF USE

(76) Inventors: Yiping Zhao, Statham, GA (US); HsiaoYun Chu, Suffern, NY (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 12/857,730

(22) Filed: Aug. 17, 2010

Related U.S. Application Data
(60) Provisional application No. 61/234,364, filed on Aug. 17, 2009.

(51) Int. Cl. G01J 3/44; B32B 5/02; B32B 27/00; B32B 15/08; B32B 27/36; C23C 14/20

(52) U.S. Cl. 356/301; 428/332; 428/411.1; 428/457; 428/480; 427/597; 977/954; 977/891

(57) ABSTRACT

Flexible SERS substrates, methods of making flexible SERS substrates, and methods of using flexible SERS substrates are disclosed.

### CROSS-REFERENCE TO RELATED APPLICATION

This application claims priority to co-pending U.S. provisional application entitled “Flexible Surface Enhanced Raman Spectroscopy (SERS) Substrates, Methods of Making, and Methods of Use,” having Ser. No. 61/234,364 filed on Aug. 17, 2009, which is entirely incorporated herein by reference.

### STATEMENT REGARDING FEDERALLY SPONSORED RESEARCH OR DEVELOPMENT

Aspects of this disclosure may have been made with government support under ECCS0701787, awarded by the National Science Foundation. The government may have certain rights in the invention(s).

### BACKGROUND

Since its first observation in the late 1970s, surface-enhanced Raman spectroscopy (SERS) has been used as an analytical tool to observe trace amounts of chemical and biological molecules due to its capability of giving real-time molecular vibrational information under ambient conditions. Because of its remarkable sensitivity, SERS has great potential in chemical and biosensing applications. To develop a reliable and efficient SERS-based sensor, the ideal SERS substrate has to be able to produce strong enhancement factors, but is also uniform, reproducible, robust, stable, and is simple and relatively inexpensive to fabricate and store.

The current SERS substrate preparation techniques include roughening of a surface by oxidation-reduction cycles (ORC), metal colloid hydrosols, laser ablation of metals by high-power laser pulses, chemical etching, roughened films prepared by Tollen's reagent, photodeposited Ag films on TiO₂, and vapor-deposited Ag metal films. Most of the above mentioned preparation methods focus on achieving large enhancement factors but do not address the need of the ideal SERS substrate. The electron beam lithography (EBL) method is an ideal method for producing uniform and reproducible substrates. Unfortunately, it is very expensive to produce large area substrates using EBL.

### SUMMARY

Flexible SERS substrates, methods of making flexible SERS substrates, and methods of using flexible SERS substrates are disclosed.

Briefly described, embodiments of the present disclosure include a flexible SERS substrate comprising a Ag nanorod array, where a length of the nanorods is about 10 nm to about 10,000 nm, a diameter of the nanorods is about 10 nm to about 150 nm, a density of the nanorods is about 11 to 2500/μm², and the nanorod array is deposited on a flexible base platform.

Embodiments of the present disclosure include a flexible SERS substrate comprising a nanorod array, where the nanorod array is deposited on a flexible base platform.

Embodiments of the present disclosure include a method of making a flexible SERS substrate using an OAD technique comprising loading a plastic sheet into an E-beam evaporator system, evaporating a base layer of metal film onto the plastic sheet, rotating the plastic sheet to less than about 89 degrees with respect to the vapor incident direction and growing nanorods on the plastic sheet.

Embodiments of the present disclosure include a method of using a flexible SERS substrate to detect at least one biomolecule in a sample comprising attaching at least one first biomolecule to an array of nanorods on the flexible substrate, exposing the flexible substrate including the first biomolecule to the sample containing at least one of a second biomolecule and a third biomolecule, and measuring a SERS spectrum, where a SERS spectrum of the array of nanorods and the first biomolecule is detectably different than a SERS spectrum of the array of nanorods, the first biomolecule, and the second biomolecule and a SERS spectrum of the array of nanorods, the first biomolecule, and the third biomolecule, and where the SERS spectrum of the array of nanorods, the first biomolecule, and the second biomolecule is detectably different than the SERS spectrum of the array of nanorods, the first biomolecule, and the third biomolecule.

Embodiments of the present disclosure include a method of using a flexible SERS substrate to detect at least one biomolecule in a sample comprising exposing the flexible substrate having an array of nanorods on the substrate to the sample, where the sample includes at least one of a first biomolecule and a second biomolecule, and measuring a SERS spectrum, where a SERS spectrum of the array of nanorods and the first biomolecule is detectably different than a SERS spectrum of the array of nanorods and the second biomolecule.

### BRIEF DESCRIPTION OF THE DRAWINGS

Many aspects of this disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a digital image that illustrates a flexible substrate.

FIG. 2 is a graph that illustrates background SERS spectra of bare Ag nanorods deposited on glass and PET substrates.

FIG. 3 is a graph that illustrates SERS spectra of BPE applied on Ag nanorod arrays deposited on glass and PET substrates.

FIG. 4 is a graph that illustrates integrated band areas at 1200 cm⁻¹ in the SERS spectra of BPE against the bending radius for Ag nanorod arrays deposited on glass and PET substrates.

FIG. 5 is a graph that illustrates the integrated band areas of the 1200 cm⁻¹ band in the SERS spectra of BPE against the curvature (expressed as 1/radius), as the substrate was subjected to cyclic concave bending (outward bending) with the induced curving strain horizontal to the Ag nanorod growth direction.

FIG. 6 is a graph that illustrates the integrated band areas of the 1200 cm⁻¹ band in the SERS spectra of BPE against the curvature (expressed as 1/radius), as the substrate was subjected to cyclic convex bending (inward bending) with the induced curving strain horizontal to the Ag nanorod growth direction.

FIG. 7 is a graph that illustrates the integrated band areas of the 1200 cm⁻¹ band in the SERS spectra of BPE against the curvature (expressed as 1/radius), as the substrate was subjected to cyclic concave bending (outward bending) with the induced curving strain perpendicular to the Ag nanorod growth direction.

FIG. 8 is a graph that illustrates the integrated band areas of the 1200 cm⁻¹ band in the SERS spectra of BPE against the curvature (expressed as 1/radius), as the substrate was subjected to cyclic convex bending (inward bending) with the induced curving strain perpendicular to the Ag nanorod growth direction.

### DETAILED DESCRIPTION

Before the present disclosure is described in greater detail, it is to be understood that this disclosure is not limited to particular embodiments described, as such may, of course, vary. It is also to be understood that the terminology used herein is for the purpose of describing particular embodiments only, and is not intended to be limiting, since the scope of the present disclosure will be limited only by the appended claims.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

The following examples are put forth so as to provide those of ordinary skill in the art with a complete disclosure and description of how to perform the methods and use the compositions and compounds disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in ° C., and pressure is at or near atmospheric. Standard temperature and pressure are defined as 20° C. and 1 atmosphere.

It must be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

### DEFINITIONS

Use of the phrase “biomolecule” is intended to encompass deoxyribonucleic acid

(DNA), ribonucleic acid (RNA), nucleotides, oligonucleotides, nucleosides, proteins, peptides, polypeptides, selenoprotiens, antibodies, combinations thereof, and the like. In particular, the biomolecule can include, but is not limited to, naturally occurring substances such as polypeptides, polynucleotides, lipids, fatty acids, glycoprotiens, carbohydrates, fatty acids, fatty esters, macromolecular polypeptide complexes, vitamins, co-factors, whole cells, eukaryotic cells, prokaryotic cells, microorganisms such as viruses, bacteria, protozoa, archaea, fungi, algae, spores, apicomplexan, trematodes, nematodes, mycoplasma, or combinations thereof.

The biomolecule may be a virus, including, but not limited to, RNA and DNA viruses. In particular the biomolecule is a virus, which may include, but is not limited to, negative-sense and positive-sense RNA viruses and single stranded (ss) and double stranded (ds) DNA viruses. The ds group I DNA viruses include the following families: Adenoviridae, Herpesviridae, Papillomaviridae, Polyomaviridae, Poxviridae, and Rudiviridae. The group II ssDNA viruses include the following families: Microviridae, Geminiviridae, Circoviridae, Nanoviridae, and Parvoviridae. The ds group III RNA viruses include the following families: Bimaviridae and Reoviridae. The group IV positive-sense ssRNA virus families: Arteriviridae, Coronaviridae, Astroviridae, Caliciviridae, Flaviviridae, Hepeviridae, Picornaviridae, Retroviridae and Togaviridae. The group V negative-sense ssRNA virus familes: Bornaviridae, Filoviridae, Paramyxoviridae, Rhabdoviridae, Arenaviridae, Bunyaviridae, and Orthomyxoviridae.

In particular embodiments the biomolecule can be one of a number of strands of the virus and/or a mutated version of a virus or of one of a number of strands of a virus. In particular, the virus can include, but is not limited to, Rotavirus.

In another aspect, the biomolecule is bacteria. The terms “bacteria” or “bacterium” include, but are not limited to, Gram positive and Gram negative bacteria. Bacteria can include, but are not limited to, Abiotrophia, Achromobacter, Acidaminococcus, Acidovorax, Acinetobacter, Actinobacillus, Actinobaculum, Actinomadura, Actinomyces, Aerococcus, Aeromonas, Afipia, Agrobacterium, Alcaligenes, Alloiococcus, Alteromonas, Amycolata, Amycolatopsis, Anaerobospirillum, Anaerorhabdus, Arachnia, Arcanobacterium, Arcobacter, Arthrobacter, Atopobium, Aureobacterium, Bacteroides, Balneatrix, Bartonella, Bergeyella, Bifidobacterium, Bilophila Branhamella, Borrelia, Bordetella, Brachyspira, Brevibacillus, Brevibacterium, Brevundimonas, Brucella, Burkholderia, Buttiauxella, Butyrivibrio, Calymmatobacterium, Campylobacter, Capnocytophaga, Cardiobacterium, Catonella, Cedecea, Cellulomonas, Centipeda, Chlamydia, Chlamydophila, Chromobacterium, Chyseobacterium, Chryseomonas, Citrobacter, Clostridium, Collinsella, Comamonas, Corynebacterium, Coxiella, Cryptobacterium, Delftia, Dermabacter, Dermatophilus, Desulfomonas, Desulfovibrio, Dialister, Dichelobacter, Dolosicoccus, Dolosigranulum, Edwardsiella, Eggerthella, Ehrlichia, Eikenella, Empedobacter, Enterobacter, Enterococcus, Erwinia, Erysipelothrix, Escherichia, Eubacterium, Ewingella, Exiguobacterium, Facklamia, Filifactor, Flavimonas, Flavobacterium, Francisella, Fusobacterium, Gardnerella, Gemella, Globicatella, Gordona, Haemophilus, Hafnia, Helicobacter, Helococcus, Holdemania Ignavigranum, Johnsonella, Kingella, Klebsiella, Kocuria, Koserella, Kurthia, Kytococcus, Lactobacillus, Lactococcus, Lautropia, Leclercia, Legionella, Leminorella, Leptospira, Leptotrichia, Leuconostoc, Listeria, Listonella, Megasphaera, Methylobacterium, Microbacterium, Micrococcus, Mitsuokella, Mobiluncus, Moellerella, Moraxella, Morganella, Mycobacterium, Mycoplasma, Myroides, Neisseria, Nocardia, Nocardiopsis, Ochrobactrum, Oeskovia, Oligella, Orientia, Paenibacillus, Pantoea, Parachlamydia, Pasteurella, Pediococcus, Peptococcus, Peptostreptococcus, Photobacterium, Photorhabdus, Phytoplasma, Plesiomonas, Porphyrimonas, Prevotella, Propionibacterium, Proteus, Providencia, Pseudomonas, Pseudonocardia, Pseudoramibacter, Psychrobacter, Rahnella, Ralstonia, Rhodococcus, Rickettsia Rochalimaea Roseomonas, Rothia, Ruminococcus, Salmonella, Selenomonas, Serpulina, Serratia, Shewenella, Shigella, Simkania, Slackia, Sphingobacterium, Sphingomonas, Spirillum, Spiroplasma, Staphylococcus, Stenotrophomonas, Stomatococcus, Streptobacillus, Streptococcus, Streptomyces, Succinivibrio, Sutterella, Suttonella, Tatumella, Tissierella, Trabulsiella, Treponema, Trophetyma, Tsakamurella, Turicella, Ureaplasma, Vagococcus, Veillonella, Vibrio, Weeksella, Wolinella, Xanthomonas, Xenorhabdus, Yersinia, and Yokenella. Other examples of bacterium include Mycobacterium tuberculosis, M. bovis, M. typhimurium, M. bovis strain BCG, BCG substrains, M. avium, M. intracellulare, M. africanum, M. kansasii, M. marinum, M. ulcerans, M. avium subspecies paratuberculosis, Staphylococcus aureus, Staphylococcus epidermidis, Staphylococcus equi, Streptococcus pyogenes, Streptococcus agalactiae, Listeria monocytogenes, Listeria ivanovii, Bacillus anthracis, B. subtilis, Nocardia asteroides, and other Nocardia species, Streptococcus viridans group, Peptococcus species, Peptostreptococcus species, Actinomyces israelii and other Actinomyces species, and Propionibacterium acnes, Clostridium tetani, Clostridium botulinum, other Clostridium species, Pseudomonas aeruginosa, other Pseudomonas species, Campylobacter species, Vibrio cholera, Ehrlichia species, Actinobacillus pleuropneumoniae, Pasteurella haemolytica, Pasteurella multocida, other Pasteurella species, Legionella pneumophila, other Legionella species, Salmonella typhi, other Salmonella species, Shigella species Brucella abortus, other Brucella species, Chlamydi trachomatis, Chlamydia psittaci, Coxiella burnetti, Escherichia coli, Neiserria meningitidis, Neiserria gonorrhea, Haemophilus influenzae, Haemophilus ducreyi, other Hemophilus species, Yersinia pestis, Yersinia enterolitica, other Yersinia species, Escherichia coli, E. hirae and other Escherichia species, as well as other Enterobacteria, Brucella abortus and other Brucella species, Burkholderia cepacia, Burkholderia pseudomallei, Francisella tularensis, Bacteroides fragilis, Fudobascterium nucleatum, Provetella species, and Cowdria ruminantium, or any strain or variant thereof.

The term biomolecule may also refer to a surface molecule or surface antigen on the surface of a pathogen (e.g., a bacterial cell), or the biomolecule is a toxin or other byproduct of a pathogen (e.g., a toxin produced by a bacterial cell). Other examples of biomolecules are viral projections such as Hemagglutinin and Neuraminidase.

Use of the phrase “peptides”, “polypeptide”, or “protein” is intended to encompass a protein, a glycoprotein, a polypeptide, a peptide, and the like, whether isolated from nature, of viral, bacterial, plant, or animal (e.g., mammalian, such as human) origin, or synthetic, and fragments thereof. A preferred protein or fragment thereof includes, but is not limited to, an antigen, an epitope of an antigen, an antibody, or an antigenically reactive fragment of an antibody.

Use of the phrase “polynucleotide” is intended to encompass DNA and RNA, whether isolated from nature, of viral, bacterial, plant or animal (e.g., mammalian, such as human) origin, synthetic, single-stranded, double-stranded, comprising naturally or non-naturally occurring nucleotides, or chemically modified.

Use of the term “affinity” can include biological interactions and chemical interactions. The biological interactions can include, but are not limited to, bonding or hybridization among one or more biological functional groups located on the first biomolecule and the second biomolecule. In this regard, the first (or second) biomolecule can include one or more biological functional groups that selectively interact with one or more biological functional groups of the second (or first) biomolecule. The chemical interaction can include, but is not limited to, bonding among one or more functional groups (e.g., organic and/or inorganic functional groups) located on the biomolecules.

Use of the term “bending cycle” means the bending of the flexible substrate convexly or concavely with a given radius, r, with respect to the base platform, and optionally, bending the substrate back to being flat. The bending cycle can be repeated. The curvature of the flexible substrate can be slight (e.g., two ends of the substrate just off from the horizontal plane of the substrate) to the ends touching upon the bending. The term “concave bending” means bending of the flexible substrate using a sequence of decreasing radii with respect to the base platform. The term “convex bending” refers to the bending of the flexible substrate using a sequence of increasing radii with respect to the base platform.

Plastics include polymers of typically high molecular weight (e.g., thermoplastics and thermosets). Plastics are capable of being molded, extruded, cast into various shapes and films, or drawn into filaments used as textile fibers. Plastics that can be used in regard to the present disclosure are those that are flexible and undergo a bending cycle, and can have nanorods deposited thereon.

### Discussion:

In accordance with the purpose(s) of the present disclosure, as embodied and broadly described herein, embodiments of the present disclosure, in one aspect, relate to flexible (e.g., bendable) SERS substrates, methods of making, and methods of use. The present disclosure further relates to the application of silver nanorod arrays deposited on plastic (e.g., polyethylene terephthalate (PET), polyether sulfone (PES), polyethylene naphthalate (PEN), polycarbonate (PC), nylon, polyether etherketone (PEEK), polysulfone (PSF), polyether imide (PEI), polyallylate (PAR), polybutylene terephthalate) by oblique angle vapor deposition (OAD) as a flexible SERS substrate for use as a versatile sensor for biomolecule and analyte detection.

It has recently been shown that oblique angle vapor deposition (OAD) can be used to prepare aligned silver nanorod arrays with surface morphologies required for SERS substrates. OAD method is based on a conventional physical vapor deposition principle and can be used to fabricate aligned and tilted Ag nanorod arrays on large substrate areas. This method involves positioning the substrate at a specific angle such that the vapor from the source is incident on the substrate close to the grazing angle (>75°. This process produces a geometric shadowing effect that results in the preferential growth of nanorods on the substrate in the direction of deposition. Silver nanorod array substrates prepared by the OAD process have previously been shown to provide SERS enhancement factors of about 10⁸. The OAD technique offers an easy, straightforward, and inexpensive method for fabrication of silver nanorod arrays for high sensitivity SERS applications.

SERS substrates produced by OAD have the advantages of uniformity and reproducibility. Currently, silicon wafers and glass slides are two of the most commonly used materials as the base platforms for OAD fabricated SERS substrates. However, these platforms are rigid and brittle. This property limits their application.

The present disclosure is directed to flexible base platforms for OAD fabricated SERS substrates. The flexible base platform may include plastic (e.g., PET), which is an inexpensive and robust material that allows for flexibility and rollability to facilitate the selection of size and shape of the SERS substrate. The flexible SERS substrates of the present disclosure retain their SERS capability under cyclic bending and flexing and can be made concave or convex relative to a planar or flat position.

Embodiments of the present disclosure can include a flexible SERS substrate, where the substrate can be subjected to cyclic concave bending with an induced curving strain horizontal to the nanorod growth direction. In an embodiment, the substrate can be subjected to cyclic convex bending with an induced curving strain horizontal to the nanorod growth direction.

Embodiments of the present disclosure can include a flexible SERS substrate, where the substrate can be subjected to cyclic concave bending with an induced curving strain perpendicular to the nanorod growth direction. In an embodiment, the substrate can be subjected to cyclic convex bending with an induced curving strain perpendicular to the nanorod growth direction.

Embodiments of the present disclosure can include flexible SERS substrates comprising a Ag nanorod array, where a length of the nanorods is about 10 nm to about 10,000 nm, a diameter of the nanorods is about 10 nm to about 150 nm, a density of the nanorods is about 11 to 2500/μm², and the nanorod array is deposited on a flexible base platform.

Embodiments of the present disclosure include flexible SERS substrates comprising a nanorod array, where the nanorod array is deposited on a flexible base platform. In an embodiment, the flexible base platform can be plastic. In another embodiment, the nanorod array is a Ag nanorod array. In an embodiment, the nanorods can be formed using a modified oblique angle deposition (OAD) technique/system (additional details are described in U.S. Pat. No. 7,658,991 B2, which is incorporated herein by reference). For example, the OAD system can include a two-axis substrate motion system in a physical vapor deposition (PVD) device (e.g., thermal evaporation, e-beam evaporation, sputtering growth, pulsed laser deposition, and the like) that operates at temperatures lower than the melting point of the material used to form the nanorods. In an embodiment, the substrate motion system provides two rotation movements: one is the polar rotation, which changes angle between the substrate surface normal and the vapor source direction, and one is the azimuthal rotation, where the sample rotates about its center axis of rotation (e.g., normal principle axis).

Embodiments of the OAD system can include a physical vapor deposition (PVD) device, such as thermal evaporation, e-beam evaporation, molecular beam epitaxy (MBE), sputtering growth, pulsed laser deposition, combinations thereof, and the like, to form the nanorods.

In addition to nanorods, the array may comprise various other nanostructures. The nanostructures can include, but are not limited to, nanorods, nanowires, nanotubes, nanospirals, combinations thereof, and the like, and uniform arrays of each. The nanostructures (e.g., nanorods) can be fabricated of one or more materials such as, but not limited to, a metal, a metal oxide, a metal nitride, a metal oxynitride, a metal carbide, a doped material, a polymer, a multicomponent compound, a compound (e.g., a compound or precursor compound (organic or inorganic compound) including a metal, a metal oxide, a metal nitride, a metal oxynitride, a metal carbide, a doped material), and combinations thereof. The metals can include, but are not limited to, silver, nickel, aluminum, silicon, gold, platinum, palladium, titanium, copper, cobalt, zinc, other transition metals, composites thereof, oxides thereof, nitrides thereof, silicides thereof, phosphides (P³⁻) thereof, oxynitrides thereof, carbides thereof, and combinations thereof. In particular the materials can include one or more of the following: silver, gold, nickel, silicon, germanium, silicon oxide, and titanium oxide. It should be noted that the nanostructure could have multiple layers of different materials or alternating materials.

The length is the largest dimension of the nanostructure and is the dimension extending from the substrate. The length/height of the nanorod can be from a few hundred nanometers or less to over a few thousand nanometers. In embodiments, the nanostructure can have a length of about 10 nm to 10000, about 10 nm to 5000 nm, about 10 nm to 4000 nm, about 10 nm to 3000 nm, about 10 nm to 2000 nm, about 10 nm to 1000 nm, about 10 nm to 500 nm, about 10 nm to 250 nm, about 10 nm to 100 nm, and about 10 nm to 50 nm. In particular, the nanostructures can have a length of about 100 nm to about 1500 nm. The length depends, at least in part, upon the deposition time, deposition rate, and the total amount of evaporating materials. The substrate can have nanorods of the same height or of varying heights on one or more portions of the substrate.

The diameter is the dimension perpendicular to the length. The diameter of the nanostructure can be about 10 to 30 nm, about 10 to 60 nm, about 10 to 100 nm, about 10 to 150 nm. In particular, the nanorods can have a diameter of about 50 to 120 nm. One or more of the dimensions of the nanostructure could be controlled by the deposition conditions and the materials.

The substrate can have from tens to tens of thousands or more nanorods formed on the substrate. The array of nanostructures can be defined as having a distance of about 10 to 30 nm, about 10 to 60 nm, about 10 to 100 nm, about 10 to 150 nm, and about 10 to 200 nm, between each of the nanostructures in the x and/or y axis (both are parallel the plane of the substrate). Alternatively, the array of nanostructures can be defined as having an average density of about 11 to 2500/μm². The number of nanorods, height and diameter of the nanorods, and the material that the nanorods of fabricated of will depend upon the specific application of the SERS system.

In embodiments of the SERS substrates of the present disclosure, the nanorods also have a tilt angle, β, formed between the nanostructure and the substrate. The angle β is less than 90°, particularly from about 0° to about 50°, and in preferred embodiments can be from about 5° to about 20°, from about 15° to about 30°, and from about 25° to about 40°. The conditions and the materials used to prepare the nanostructure can be used to determine/select the tilt angle. The tilt angle is important in creating SERS enhancement factors with sufficient sensitivity to detect binding of an analyte of interest to the SERS sensors of the present disclosure.

Embodiments of the present disclosure include flexible SERS substrates where the base platform is polyethylene terephthalate (PET).

Embodiments of the present disclosure include flexible SERS substrates where the surface enhancement factor is comparable to a Ag nanorod array SERS substrate deposited on a glass base platform. The surface enhancement factor allows for sufficient sensitivity to detect binding of a biomolecule of interest to the SERS substrate (e.g., enhancement factor of about 10⁶, about 10⁷, about 10⁸ or more). In an embodiment, the flexible SERS substrate substantially (e.g., about 80% or more, 90% or more, 95% or more, 99% or more) or completely retains its SERS capability under cyclic bending and flexing. In another embodiment, the flexible SERS substrate substantially (e.g., about 80% or more, 90% or more, 95% or more, 99% or more) or completely retains its SERS capability when bent convexly or concavely.

Embodiments of the present disclosure can include a flexible SERS substrate where the substrate has a bend selected from a convex bend, a concave bend, and a combination thereof.

Embodiments of the present disclosure include methods of making a flexible SERS substrate using an OAD technique comprising cutting a plastic sheet into a desirable size (or otherwise obtaining a sheet of desirable size), cleaning the plastic sheet (e.g., with commercial detergent and deionized water), drying the plastic sheet (e.g., with a stream of nitrogen gas), loading the plastic sheet into an E-beam evaporator system, evaporating a base layer of metal (e.g., Ti and/or Ag) film onto the plastic sheet, rotating the plastic sheet to about 89 degrees or less (e.g., about 50 to 89 degrees or about 86 degrees) with respect to the vapor incident direction, and growing nanorods (e.g., Ag nanorods) on the plastic sheet.

In an embodiment, the method further includes evaporating the base layer at a rate of about 0.2 nm/s for the Ti and about 0.3 nm/s for the Ag. In some embodiments the thickness of the film is from about 10 nm to about 1000 nm; in a particular embodiment it is between about 50 nm and about 500 nm. In another embodiment, the method further includes growing the nanorods (e.g., Ag nanorods) to the dimensions as described above with a deposition rate of about 0.3 nm/s and a deposition pressure of about 1×10⁻⁶ Torr.

Embodiments of the present disclosure include methods of making a flexible SERS substrate where the nanorods comprise Ag nanorods, a length of the nanorods is about 10 nm to about 10,1000 nm, a diameter of the nanorods is about 10 nm to about 150 nm, and a density of the nanorods is about 11 to 2500/μm².

Embodiments of the present disclosure include methods of using a flexible SERS substrate to detect at least one biomolecule in a sample comprising attaching at least one first biomolecule to an array of nanorods on the flexible substrate, exposing the flexible substrate including the first biomolecule to the sample containing at least one of a second biomolecule and a third biomolecule, and measuring a SERS spectrum, where a SERS spectrum of the array of nanorods and the first biomolecule is detectably different than a SERS spectrum of the array of nanorods, the first biomolecule, and the second biomolecule and a SERS spectrum of the array of nanorods, the first biomolecule, and the third biomolecule, and where the SERS spectrum of the array of nanorods, the first biomolecule, and the second biomolecule is detectably different than the SERS spectrum of the array of nanorods, the first biomolecule, and the third biomolecule. In an embodiment, the flexible SERS substrate is in a concave shape, a convex shape, or a combination thereof (e.g., part of the substrate is concave and the other part is convex (e.g., a wave-like shape)).

In an embodiment, the first biomolecule is selected from a polynucleotide, a protein, a polypeptide, a glycoprotein, a lipid, a carbohydrate, a fatty acid, a fatty ester, a macromolecular polypeptide complex, and a combination thereof.

In another embodiment, each of the second biomolecule and the third biomolecule are a virus.

In yet another embodiment, each of the second biolmolecule and the third biomolecule are a bacterium.

Embodiments of the present disclosure include methods for detecting an analyte of interest (e.g., melamine) in a sample.

Embodiments of the present disclosure include methods of using a flexible SERS substrate to detect at least one biomolecule in a sample comprising exposing the flexible substrate having an array of nanorods on the substrate to the sample, where the sample includes at least one of a first biomolecule and a second biomolecule, and measuring a SERS spectrum, where a SERS spectrum of the array of nanorods and the first biomolecule is detectably different than a SERS spectrum of the array of nanorods and the second biomolecule.

Embodiments of the present disclosure include methods of using a flexible SERS substrate where the nanorods comprise Ag nanorods, a length of the nanorods is about 10 nm to about 10,1000 nm, a diameter of the nanorods is about 10 nm to about 150 nm, and a density of the nanorods is about 11 to 2500/μm².

### EXAMPLES

### Introduction

Since its first observation in the late 1970s, surface-enhanced Raman spectroscopy (SERS) has been used as an analytical tool to observe trace amounts of chemical and biological molecules due to its capability of giving real-time molecular vibrational information under ambient conditions. Because of its remarkable sensitivity, SERS has great potential in chemical and biosensing applications. To develop a reliable and efficient SERS-based sensor, the ideal SERS substrate has to be able to produce strong enhancement factors, but is also uniform, reproducible, robust, stable, and is simple and relatively inexpensive to fabricate and store.

The current SERS substrate preparation techniques include roughening of a surface by oxidation-reduction cycles (ORC) (M. Fleischmann et al., Chem. Phys. Lett. 26 (1974), p. 163, which is herein incorporated by reference for the corresponding discussion), metal colloid hydrosols (A. M. Ahern and R. L. Garrell, Anal. Chem. 59 (1987), p. 2813, which is herein incorporated by reference for the corresponding discussion), laser ablation of metals by high-power laser pulses (J. Neddersen et al., Appl. Spectrosc. 47 (1993), p. 1959, which is herein incorporated by reference for the corresponding discussion), chemical etching (G. Xue et al., Appl. Spectrosc. 45 (1991), p. 756., which is herein incorporated by reference for the corresponding discussion), roughened films prepared by Tolien's reagent (K. L. Norrod et al., Appl. Spectrosc. 51 (1997), p. 994, which is herein incorporated by reference for the corresponding discussion), photodeposited Ag films on TiO₂ (K. L. Norrod et al., Appl. Spectrosc. 51 (1997), p. 994, which is herein incorporated by reference for the corresponding discussion), and vapor-deposited Ag metal films (V. L. Schlegel and T. M. Cotton, Anal. Chem. 63 (1991), p. 241; R. P. Van Duyne et al., J. Chem. Phys. 99 (1993), p. 2101; D. J. Semin and K. L. Rowlen, Anal. Chem. 66 (1994), p. 4324; S. E. Roark and K. L. Rowlen, Anal. Chem. 66 (1994), p. 261, which are herein incorporated by reference for the corresponding discussion). Most of the above mentioned preparation method focus on achieving large enhancement factors but do not address the need of the ideal SERS substrate. The electron beam lithography (EBL) method is an ideal method for producing uniform and reproducible substrates (M. Kahl et al., Sens. Actuators B 51 (1998), p. 285; M. A. De Jesus et al., Appl. Spectrosc. 59 (2005), p. 1501; M. Sackmann et al., J. Raman Spectrosc. 38 (2007), p. 277; L. Billot et al., Chem. Phys. Lett. 422 (2006), p. 303; T. H. Reilly et al., Anal. Chem. 79 (2007), p. 5078, which are herein incorporated by reference for the corresponding discussion). Unfortunately, it is very expensive to produce large area substrates using EBL.

We have recently shown that oblique angle vapor deposition (OAD) can be used to prepare aligned silver nanorod arrays with surface morphologies required for surface-enhanced Raman scattering (SERS) substrates (S. B. Chaney et al., Appl. Phys. Lett. 87 (2005), p. 31908; S. Shanmukh et al., Nano Lett. 6 (2006), p. 2630; Y.-P. Zhao et al., J. Phys. Chem. B 110 (2006), p. 3153, which are herein incorporated by reference for the corresponding discussion). OAD method is based on a conventional physical vapor deposition principle and can be used to fabricate aligned and tilted Ag nanorod arrays on large substrate areas. This method involves positioning the substrate at a specific angle such that the vapor from the source is incident on the substrate close to the grazing angle)(>75°. This process produces a geometric shadowing effect that results in the preferential growth of nanorods on the substrate in the direction of deposition. Silver nanorod array substrates prepared by the OAD process have previously been shown to provide SERS enhancement factors of ˜10⁸ (S. B. Chaney et al., Appl. Phys. Lett. 87 (2005), p. 31908; Y.-J. Liu et al., Appl. Phys. Lett. 89 (2006), p. 173134; J. Driskell et al., J. Phys. Chem. C 112 (2008), p. 895; H. Y. Chu et al., Opt. Exp. 15 (2007), p. 12230, which are herein incorporated by reference for the corresponding discussion). The OAD technique offers an easy, straightforward, and inexpensive method for fabrication of silver nanorod arrays for high sensitivity SERS applications. The SERS substrates produced by OAD have the advantages of uniformity and reproducibility. Currently, silicon wafers and glass slides are two of the most commonly used materials as the base platforms for OAD fabricated SERS substrates. However, they are rigid and brittle. This property limits their application as flexible substrates. Plastics are a good alternative to the glass substrates. It is an inexpensive and robust material. Its flexibility and rollability facilitate the selection of size and shape of the SERS substrate and allows reasonable tradeoffs in mechanical and optical performance.

In this work, we report the characterization of Ag nanorod arrays deposited on PET by the OAD technique as a flexible SERS substrate. In particular, we report the SERS response of the substrate undergoing cyclic bending cycle.

### Experimental

### Fabrication of Substrates

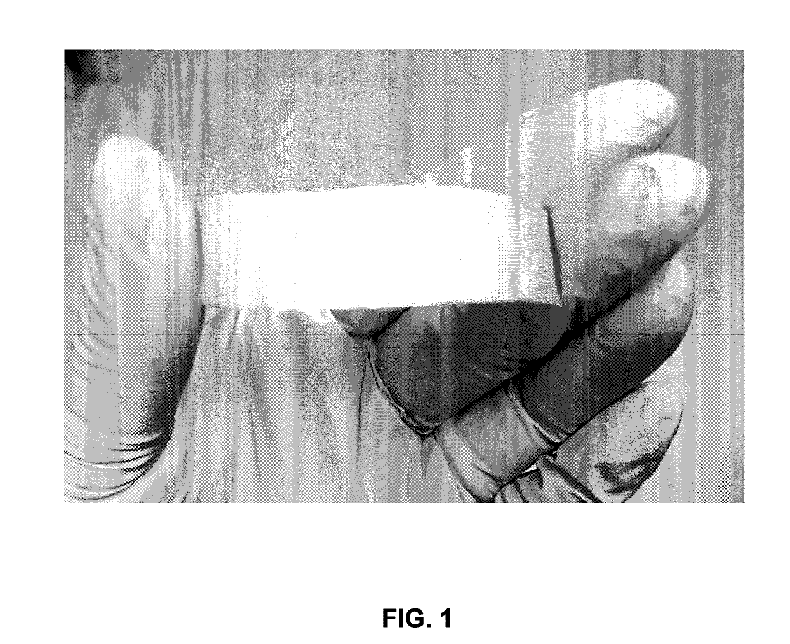

The SERS active substrates used were silver nanorod arrays fabricated using the OAD technique using a custom-designed electron beam evaporation (E-beam) system (Torr International, New Windsor, N.Y.) that has been previously described. Polyethylene terephthalate (PET) plastic sheets (DuPont Teijin Films, Hopewell, Va.) were used as the base platform for silver nanorod array deposition. The PET sheet was cut into desirable sizes and cleaned with commercial detergent and deionized water. The substrates were then dried with a stream of nitrogen gas before loading into the E-beam evaporator system. The source material for evaporation was Titanium pellets (Kurt J. Lesker, Clariton, Pa., 99.995%) and Ag pellets (Kurt J. Lesker, Clariton, Pa., 99.999%). A base layer of Ti (20 nm) and silver film (500 nm) were first evaporated onto the plastic sheets at normal angle to the substrate surface at a rate of 0.2 nm/s and 0.3 nm/s, respectively. The substrates were then rotated to 86° with respect to the vapor incident direction. Ag nanorods were grown at this oblique angle with a nominal deposition rate of 0.3 nm/s and a deposition pressure of ˜1×10⁻⁶ Torr. The film thickness was monitored by a quartz crystal microbalance positioned at normal incidence to the vapor source direction. FIG. 1 shows the image of the flexible substrate.

### Surface-Enhanced Raman Scattering Measurements

The SERS spectra were acquired using a HRC-10HT Raman analyzer system (Enwave Optronics Inc. Irvine, Calif.). This system consists of a diode laser, spectrometer, integrated Raman probe head for both excitation and collection, and separate delivery and collection fibers. The excitation source was a frequency stabilized, narrow linewidth near-infrared diode laser with a wavelength of 785 nm. The excitation laser beam coupled to a 100 μm fiber was focused onto the substrate through the Raman probe head and was unpolarized at the sample. The focal length of the Raman probe was 6 mm, and the diameter of the laser spot was 0.1 mm. The Raman signal from the substrate was collected by the same Raman probe head and was coupled to a 200 μm collection fiber that delivered the signal to the spectrometer equipped with a charge-coupled device (CCD) detector. The laser power at the sample was monitored with a power meter (PM 121, Thorlabs Inc., Newton, N.J.) was 20 mW (λ=785 nm). The spectral collection time was 10 s. The molecular probe used in this study was trans-1,2-bis(4-pyridyl)ethene (BPE, 99.9+%, Sigma). BPE solutions were prepared by sequential dilution in ACS grade methanol (Fisher Scientific). For each concentration, a 2 μl drop of BPE solution was applied onto the silver nanorod substrate and allowed to dry before the acquisitions of data. SERS spectra were collected from multiple points across the substrate.

### Bending Cycle

The SERS performance of silver nanorod array substrates under bending are analyzed according to the bending radius and the bending cycles. A complete bending cycle consists of continuously bending substrate on sequences of decreasing radius (r=4.25, 3.5, 2.75 and 2.25 inches) and then relaxing the substrate on sequences of increasing radius (r=2.75, 3.5 and 4.25 inches). The effect of bending direction of the substrate, i.e., the induced strain from curving perpendicular or horizontal to the silver nanorod growth direction, was also evaluated.

### Results and Discussion

### Surface-Enhanced Raman Scattering of Flexible Substrate

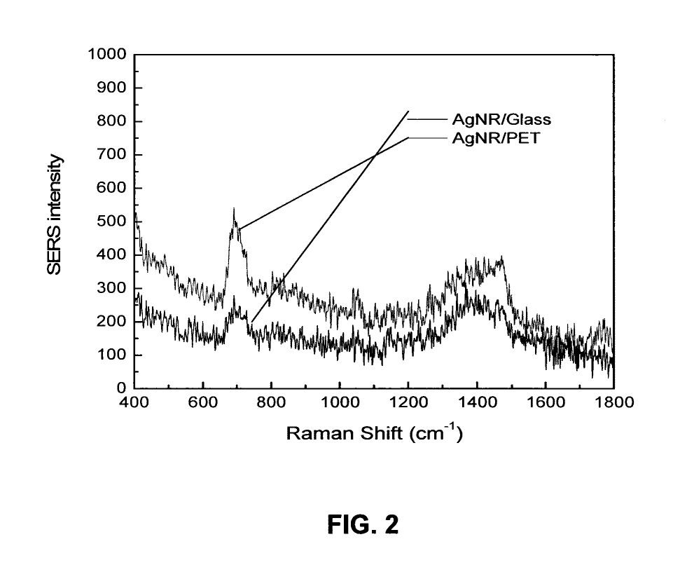

FIG. 2 shows the representative background SERS spectra of the bare silver nanorod arrays deposited on a glass surface and on a PET substrate after the fabrication process and before any analyte molecules were applied on the substrate. Two broad peaks can be seen in the background spectra at around 700 and 1400 cm⁻¹. Similar background spectra were collected from multiple substrates with no difference in band positions. The broad peak around 1400 cm⁻¹ could be ascribed to the disorder in the graphite chain. Vapor deposited silver films and electrochemically reduced silver electrodes have been reported to exhibit backgrounds due to graphitic carbonaceous adsorption onto the substrate (K. L. Norrod et al., Appl. Spectrosc. 51 (1997), p. 994; C. E. Taylor et al., Anal. Chem. 68 (1996), p. 2401, which are herein incorporated by reference for the corresponding discussion). The other band in the spectra possibly arises from organic impurities out-gassing from the deposition chamber.

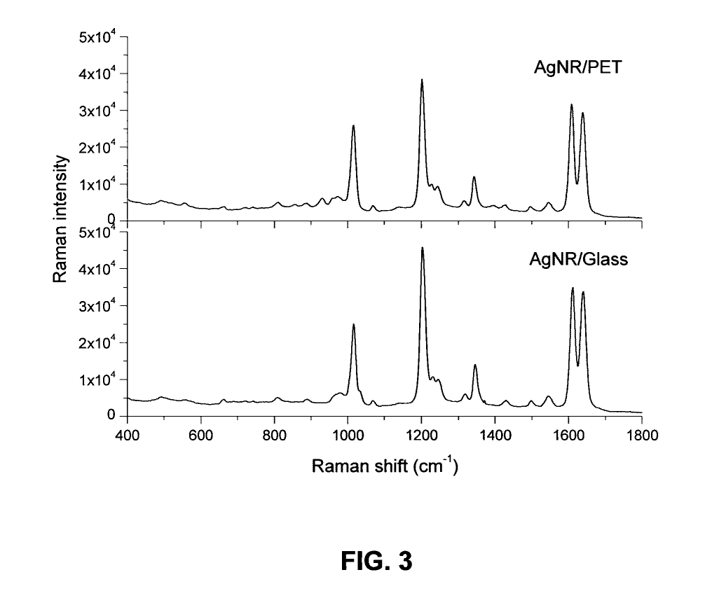

To characterize the SERS response of the flexible substrates, Raman spectra of BPE were collected by spreading 2 μL of a 10⁻⁵ M BPE solution in methanol on the surface. The SERS spectra of BPE on the Ag nanorod arrays deposited on a glass substrate and on a PET substrate are shown in FIG. 3. There is no difference in the positions of the major bands of BPE between spectra observed for both substrates. The main bands of BPE at around 1200, 1610 and 1640 cm⁻¹ can be assigned to the ethylenic C═C in-plane ring mode, aromatic ring stretching mode, and the C═C stretching mode, respectively (W. H. Yang et al. J. Chem. Phys. 104 (1996), p. 4313, which is herein incorporated by reference for the corresponding discussion). Additionally, the similarity in the relative band intensities of BPE spectra for both substrates, indicating that the surface enhancement factor for Ag nanorod arrays deposited on PET substrate is comparable to that of glass substrate.

### Effect of Bending on the SERS Spectra

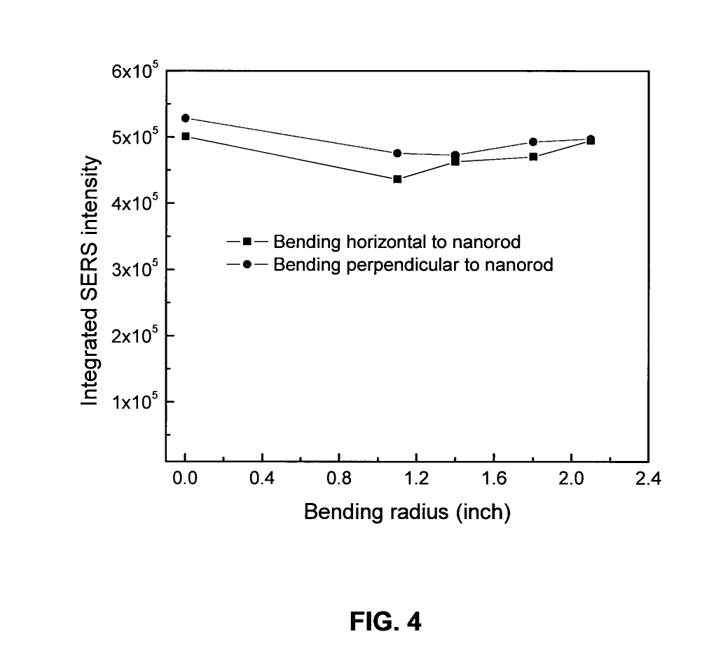

In order for the substrate to be an effective sensor, the flexible substrate must retain the SERS capability under bending. Although a number of deformation geometries of flexible substrates are possible, the simplest configuration is bending convexly or concavely with a given radius r. In this study, the SERS response of flexible substrates under bending are analyzed according to the bending radius and cycles. FIG. 4 shows the integrated band areas of the 1200 cm⁻¹ band in the SERS spectra of BPE against the bending radius for Ag nanorod arrays deposited on glass and PET substrates. As seen in FIG. 4, the SERS response remains relatively stable under different bending radius regardless of the nanorod direction to the bending stress for both glass and PET substrates, although, a slight decrease in SERS response can be seen with smaller bending radius.

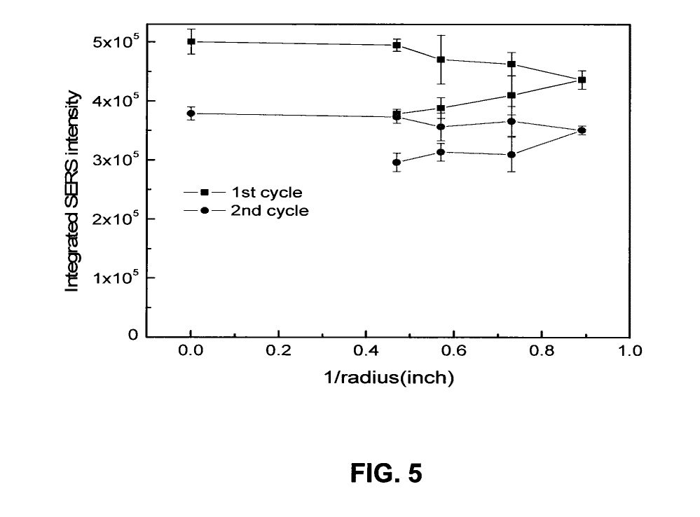

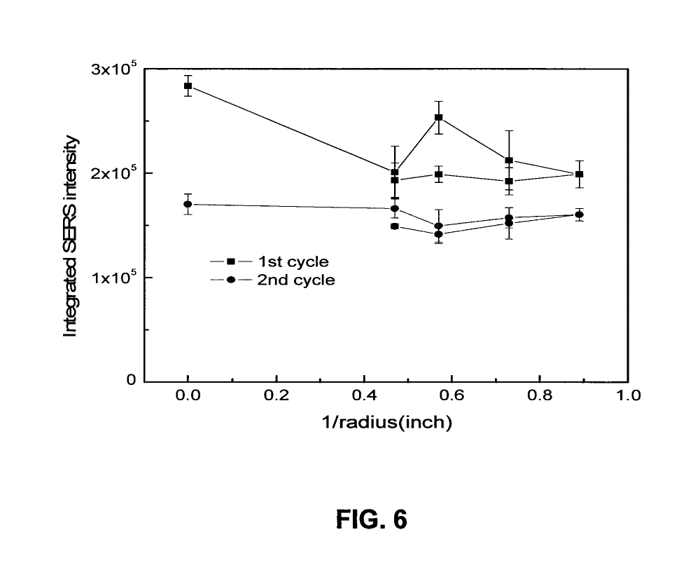

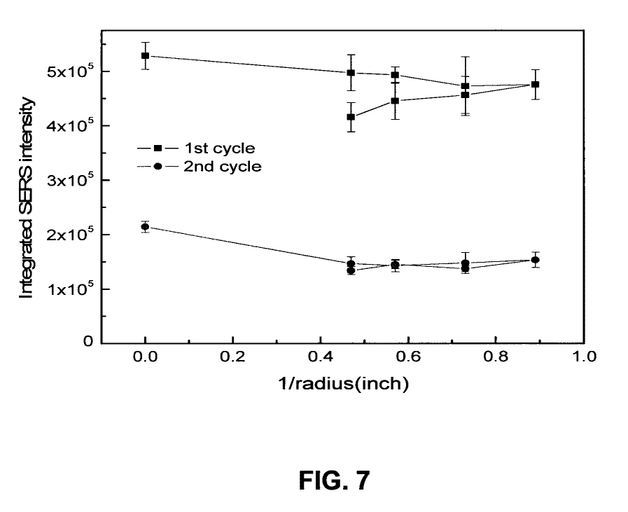

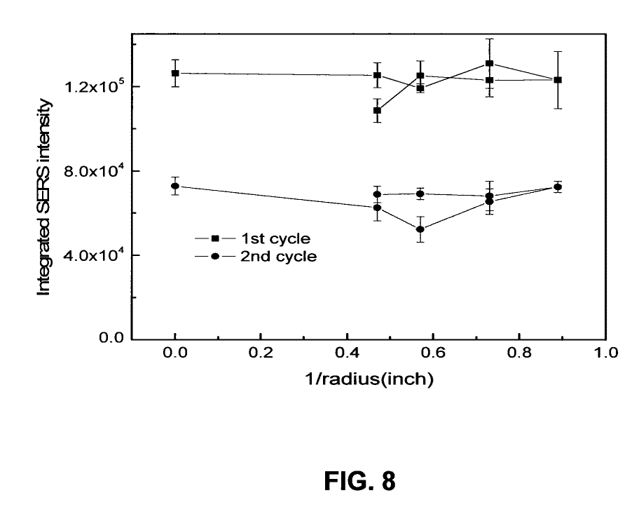

To investigate the effect of cyclic bending on the change in the SERS response, Ag nanorod flexible substrate was subjected to two complete bending cycles consisting of continuously bending the substrate on sequences of decreasing radius (r=4.25, 3.5, 2.75 and 2.25 inches) and then relaxing the substrate on sequences of increasing radius (r=2.75, 3.5 and 4.25 inches). The SERS response to cyclic flexing the substrates concavely and convexly with the induced curving strain horizontal to the Ag nanorod growth direction are shown in FIGS. 5 and 6. The SERS responses decreased gradually as the substrate went through cyclic bending. At the end of two complete bending cycles, the bent substrate retained approximately 50% SERS activity of that from the substrate before bending. FIGS. 7 and 8 show the SERS response to cyclic flexing the substrates concavely and convexly with the induced curving strain perpendicular to the Ag nanorod growth direction. As can be seen, inducing strain perpendicular to the Ag nanorod array direction appears to result in a larger decrease of SERS response as substrates going through cyclic bending.

### CONCLUSION

OAD fabricated Ag nanorod arrays have been shown to be excellent SERS substrates. In this study, we demonstrate that Ag nanorod arrays deposited on PET substrates produce comparable SERS response to those deposited on glass slides. We also demonstrate that PET substrates retain reasonable SERS response after undergoing cyclic bending and flexing. The flexibility of SERS PET substrates makes it a great candidate for developing low-cost, disposable and versatile sensor.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of the numerical value. In addition, the phrase “about ‘x’ to ‘y’” includes “about ‘x’ to about ‘y’”.

It should be emphasized that the above-described embodiments of the present disclosure are merely possible examples of implementations, and are merely set forth for a clear understanding of the principles of the disclosure. Many variations and modifications may be made to the above-described embodiments. All such modifications and variations are intended to be included herein within the scope of this disclosure and protected by the following claims.

Therefore, at least the following is claimed:

1. A flexible SERS substrate comprising:
a Ag nanorod array, wherein a length of the nanorods is about 10 nm to about 10,000 nm, wherein a diameter of the nanorods is about 10 nm to about 150 nm, wherein a density of the nanorods is about 11 to 2500/μm², and wherein the nanorod array is deposited on a flexible base platform.

2. A flexible SERS substrate comprising:
a nanorod array, wherein the nanorod array is deposited on a flexible base platform.

3. The flexible SERS substrate of claim 2, wherein the nanorod array is a Ag nanorod array.

4. The flexible SERS substrate of claim 2, wherein the substrate is fabricated by oblique angle deposition (OAD).

5. The flexible SERS substrate of claim 2, wherein the flexible base platform is plastic.

6. The flexible SERS substrate of claim 5, wherein the flexible base platform is polyethylene terephthalate (PET).

7. The flexible SERS substrate of claim 2, wherein the surface enhancement factor is about 10⁸.

8. The flexible SERS substrate of claim 2, wherein the substrate retains its SERS capability under cyclic bending and flexing.

9. The flexible SERS substrate of claim 8, wherein the substrate has a bend selected from a convex bend, a concave bend, and a combination thereof.

10. A method of making a flexible SERS substrate using an OAD technique comprising:
loading a plastic sheet into an E-beam evaporator system;
evaporating a base layer of metal film onto the plastic sheet;
rotating the plastic sheet to less than about 89 degrees with respect to the vapor incident direction; and
growing nanorods on the plastic sheet.

11. The method of claim 10, further comprising:
preparing the plastic sheet for deposition of the nanorods, wherein the plastic sheet is cut into a desirable size, wherein the plastic sheet is cleaned with deionized water, and wherein the plastic sheet is dried with a stream of nitrogen gas.

12. The method of claim 10, wherein the nanorods comprise Ag nanorods, wherein a length of the nanorods is about 10 nm to about 10,000 nm, wherein a diameter of the nanorods is about 10 nm to about 150 nm, and wherein a density of the nanorods is about 11 to 2500/μm².

13. The method of claim 10, further comprising:
evaporating the base layer at a rate of about 0.2 nm/s for Ti and about 0.3 nm/s for Ag nanorods.

14. The method of claim 10, further comprising:
growing Ag nanorods with a deposition rate of about 0.3 nm/s and a deposition pressure of about 1×10⁻⁶ Torr.

15. A method of using a flexible SERS substrate to detect at least one biomolecule in a sample comprising:
attaching at least one first biomolecule to an array of nanorods on the flexible substrate;
exposing the flexible substrate including the first biomolecule to the sample containing at least one of a second biomolecule and a third biomolecule; and
measuring a SERS spectrum, wherein a SERS spectrum of the array of nanorods and the first biomolecule is detectably different than a SERS spectrum of the array of nanorods, the first biomolecule, and the second biomolecule and a SERS spectrum of the array of nanorods, the first biomolecule, and the third biomolecule, and wherein the SERS spectrum of the array of nanorods, the first biomolecule, and the second biomolecule is detectably different than the SERS spectrum of the array of nanorods, the first biomolecule, and the third biomolecule.

16. The method of claim 16, wherein the nanorods comprise Ag nanorods, wherein a length of the nanorods is about 10 nm to about 10,000 nm, wherein a diameter of the nanorods is about 10 nm to about 150 nm, and wherein a density of the nanorods is about 11 to 2500/μm².

17. The method of claim 15, wherein the first biomolecule is selected from the group consisting of: a polynucleotide, a protein, a polypeptide, a glycoprotein, a lipid, a carbohydrate, a fatty acid, a fatty ester, a macromolecular polypeptide complex, and a combination thereof.

18. The method of claim 15, wherein each of the second biomolecule and the third biomolecule are a virus.

19. The method of claim 15, wherein each of the second biolmolecule and the third biomolecule are a bacterium.

20. A method of using a flexible SERS substrate to detect at least one biomolecule in a sample comprising:
exposing the flexible substrate having an array of nanorods on the substrate to the sample, wherein the sample includes at least one of a first biomolecule and a second biomolecule; and
measuring a SERS spectrum, wherein a SERS spectrum of the array of nanorods and the first biomolecule is detectably different than a SERS spectrum of the array of nanorods and the second biomolecule.

21. The method of claim 20, wherein the nanorods comprise Ag nanorods, wherein a length of the nanorods is about 10 nm to about 10,000 nm, wherein a diameter of the nanorods is about 10 nm to about 150 nm, and wherein a density of the nanorods is about 11 to 2500/μm².
